(19) United States
(12) Patent Application Publication
(10) Pub. No.: US 2026/0074669 A1
(43) Pub. Date: Mar. 12, 2026

(54) Substrate, Electronic Device, and Module

(71) Applicant: QUANZHOU SANAN INTEGRATED CIRCUIT CO., LTD., Quanzhou (CN)

(72) Inventors: Minghui FANG, Quanzhou (CN); Zhonghe LIN, Quanzhou (CN); Shihwei HUANG, Quanzhou (CN); Yilin LIU, Quanzhou (CN)

(21) Appl. No.: 19/305,766

(22) Filed: Aug. 21, 2025

(30) Foreign Application Priority Data
Sep. 6, 2024 (CN) 2024112446267

(51) Int. Cl. H03H 9/02; H01L 25/16; H03H 9/17

(52) U.S. Cl. CPC H03H 9/02543; H03H 9/02992; H03H 9/17; H10W 90/00

(57) ABSTRACT

A substrate, an electronic device, and a module are provided. The substrate provided by embodiments includes a carrier substrate formed from a polycrystalline material having a main support surface, where an observation region on the main support surface or on any transverse interface parallel to the main support surface contains (101)-oriented crystal grains, and a proportion of the (101)-oriented crystal grains in the observation region is 7% to 20% of a total number of grains in the observation region, and where the observation region measures 150 μm×150 μm.

### CROSS-REFERENCE TO RELATED APPLICATION

The present disclosure claims priority to Chinese Patent Application No. 202411244626.7 filed on Sep. 6, 2024, the contents of which are herein incorporated by reference in its entirety.

### THCHNICAL FIELD

This application relates to the field of mobile communication devices and, more particularly, to a substrate, an elastic wave device and a communication module including the elastic wave device.

### BACKGROUND

The Q value (resonator quality factor) is an important parameter for describing the performance of a resonator, and is particularly important in resonators, filters, and other electronic components operating at radio frequencies and microwave frequencies. In existing elastic wave filters, such as surface acoustic wave (SAW) filter devices, improvements have been made in the design of the piezoelectric layer or the interdigital transducer (IDT) electrodes.

### SUMMARY

Some examples described herein may have an object to provide a substrate with a specific crystallographic orientation ratio, which can effectively improve the Q-factor of electronic devices.

In some examples, a substrate is provided, comprising a carrier substrate formed from a polycrystalline material having a main support surface, wherein an observation region on said main support surface or on any transverse interface parallel to said main support surface contains (101)-oriented crystal grains, and a proportion of said (101)-oriented crystal grains in said observation region is 7% to 20% of a total number of grains in said observation region, and wherein said observation region measures 150 μm×150 μm.

In some examples, an electronic device is provided, comprising:
a substrate, comprising a carrier substrate formed from a polycrystalline material having a main support surface, wherein an observation region on said main support surface or on any transverse interface parallel to said main support surface contains (101)-oriented crystal grains, and a proportion of said (101)-oriented crystal grains in said observation region is 7% to 20% of a total number of grains in said observation region, and wherein said observation region measures 150 μm×150 μm;
a piezoelectric layer provided on the main support surface of the carrier substrate; and
an IDT electrode provided on a main surface of the piezoelectric layer opposite to the carrier substrate.

In some examples, a module is provided that includes a wiring substrate, a plurality of external connection terminals, an integrated circuit component, an inductor, a sealing portion, and the above-described electronic device.

The embodiments of this disclosure provide at least one or more of the following advantageous effects: By providing a carrier substrate having a specific grain density, enhanced flexural strength can be achieved, which prevents chipping during subsequent bonding processes, thereby ensuring both production quality and efficiency.

Details of one or more embodiments of the present application are set forth in the accompanying drawings and the description below. Other features, objects, and advantages of the present application will become apparent from the description and drawings, and from the claims.

### BRIEF DESCRIPTION OF DRAWINGS

The patent or application file contains at least one drawing executed in color. Copies of this patent or patent application publication with color drawings will be provided by the Office upon request and payment of the necessary fee.

The accompanying drawings are intended to provide a further understanding of the present application, constitute part of this application, and illustrate exemplary embodiments of this application. The description and drawings do not limit the scope of the application.

FIG. 1 is a schematic structural diagram of a carrier substrate according to one embodiment of the present disclosure.

FIG. 2 is a distribution diagram of crystal grains of various orientations in a carrier substrate according to one embodiment of the present disclosure.

FIG. 3 is a distribution diagram of crystal grains of various orientations in a carrier substrate according to another embodiment of the present disclosure.

FIG. 4 is a distribution diagram of crystal grains of various orientations in a carrier substrate according to yet another embodiment of the present disclosure.

FIG. 5 is a distribution diagram of crystal grains of various orientations in a carrier substrate according to still another embodiment of the present disclosure.

FIG. 6 is a schematic structural diagram of a composite substrate according to one embodiment of the present disclosure.

FIG. 7 is a schematic structural diagram of an electronic device according to one embodiment of the present disclosure.

FIG. 8 is a schematic structural diagram of an electronic device according to another embodiment of the present disclosure.

FIG. 9 is a schematic structural diagram of an electronic device according to yet another embodiment of the present disclosure.

FIG. 10 is a schematic structural diagram of an electronic device according to still another embodiment of the present disclosure.

FIG. 11 is a schematic diagram showing a module according to one embodiment.

### DETAILED DESCRIPTION OF EMBODIMENTS

The embodiments will be described with reference to the accompanying drawings. In the drawings, the same or corresponding parts are denoted by the same reference numerals. Duplicate descriptions of such portions may be simplified or omitted.

In order to make the objectives, features, and advantages of the present disclosure more clearly understood, specific embodiments of the disclosure are described in detail below with reference to the accompanying drawings.

To facilitate a better understanding of the technical solutions of the disclosure for those skilled in the art, the following descriptions of the embodiments of the disclosure are provided clearly and comprehensively with reference to the accompanying drawings. It should be understood that the described embodiments are only part of the disclosure and not exhaustive. All other embodiments obtained by those skilled in the art without involving inventive activity, based on the disclosed embodiments, shall fall within the scope of protection of the disclosure.

It should also be noted that the terms “first,” “second,” and so on, used in the specification, claims, and drawings of the disclosure, are merely to distinguish similar elements and do not imply a particular sequence or order. These terms can be used interchangeably when appropriate, so that the embodiments of the disclosure can be implemented in sequences other than those illustrated or described. Furthermore, the terms “include”, “comprise” and variations thereof are intended to be non-exclusive. For example, a process, method, system, product, or apparatus that comprises a series of steps or elements is not limited to only those explicitly listed but may also include other steps or elements that are inherent or not expressly stated.

Additionally, it should be noted that the division of embodiments in this disclosure is made for ease of explanation and should not be interpreted as limiting. Features of the various embodiments may be combined or referenced where there is no conflict.

Referring to FIG. 1, an embodiment of the present disclosure provides a carrier substrate 11. The carrier substrate 11 is made of a polycrystalline material and has a main support surface 111. An observation region on the main support surface 111 or on any transverse interface parallel to the main support surface 111 contains (101)-oriented crystal grains. In the observation region, the proportion of the number of (101)-oriented crystal grains to the total number of crystal grains in the observation region is more than or equal to 7%. The observation region is an area of 150 micrometers×150 micrometers. In brief, in the observation region, the proportion of (101)-oriented crystal grains is more than or equal to 7%. In some specific embodiments, the proportion of (101)-oriented crystal grains in the observation region is 7% to 20%, including but not limited to 7%, 10%, 12%, 15%, and 19%.

The carrier substrate 11 may be, for example, a spinel-type material containing a plurality of crystal grains, which typically exhibit a spinel crystal structure. Specifically, in a spinel crystal structure, oxygen ions are arranged in a cubic close-packed (ccp) configuration, divalent cations occupy one-eighth of the tetrahedral voids, and trivalent cations occupy one-half of the octahedral voids. The general formula is AB₂O₄, where A is an element of the divalent cation, B is an element of the trivalent cation, and O is oxygen. Magnesium aluminate spinel (molecular formula MgAl₂O₄) is a typical example of a spinel-type structure. In some embodiments, the main material of the carrier substrate 11 is, for example, polycrystalline magnesium aluminate spinel.

The average grain size of the crystal grains in the carrier substrate 11 ranges from 1 to 100 μm. That is, the carrier substrate may contain crystal grains of different sizes, for example, crystal grains with particle sizes of 3 μm, 25 μm, 40 μm, 50 μm, 60 μm, 100 μm, etc., and the smallest particle size of the grains is not less than 1 μm (21 μm), while the largest particle size of the grains does not exceed 100 μm (≤100 μm). The average grain size of these different particle sizes is the average grain size of the carrier substrate 11. The calculation of the average grain size may, for example, involve dividing the carrier substrate 11 into multiple regions, counting the number of grains of each size in each region, using the number corresponding to each grain size as a weighting factor to calculate an average, i.e., the average grain size of the carrier substrate 11 is the weighted average of the particle sizes of all the crystal grains in the carrier substrate.

The main support surface 111 is used to support a piezoelectric layer, that is, the main support surface 111 is the surface facing the piezoelectric layer when the carrier substrate 11 is combined with the piezoelectric layer. Correspondingly, the carrier substrate 11 further has a back surface 112 opposite to the main support surface 111. The transverse interface may be, for example, the back surface 112, or it may be a cross-section parallel to the main support surface 111. For example, referring to the position indicated by the A-A dashed line (parallel to the main support surface 111) in FIG. 1, when the carrier substrate 11 is cut into an upper portion and a lower portion, the main support surface 111 is located on the upper portion and the back surface 112 is located on the lower portion. In this case, the lower surface of the upper portion and the upper surface of the lower portion are both transverse interfaces parallel to the main support surface 111.

The observation region is any square region on the corresponding surface with a length of 150 μm and a width of 150 μm. In other words, an observation surface is selected on the main support surface 111 or on any transverse interface parallel to the main support surface 111, and any 150 μm×150 μm region on that observation surface can be selected as the observation region.

The term “(101)-oriented crystal grain” means that, in the observation region, if the (101) crystal plane of a crystal grain is oriented toward the plane of the observation region, then that crystal grain is a (101)-oriented crystal grain. The (101) orientation includes the direction and its two opposite directions. The proportion of (101)-oriented crystal grains in the observation region can be determined by obtaining a microstructural image of the observation region using Electron Backscatter Diffraction (EBSD) technology and performing Inverse Pole Figure (IPF) coloring on the microstructure of the observation region. IPF coloring is a method used in materials science to characterize crystal orientations. It represents the orientation information of a crystal in a polar coordinate diagram using colors, allowing the observer to visually identify the texture characteristics of the crystal. Specifically, after IPF coloring, crystal grains of different orientations are displayed in different colors, and the proportion of crystal grains of a given orientation in the observation region can be obtained by counting the grains of the corresponding color and dividing by the total number of grains in the observation region. The above calculation process can be performed by detection equipment having IPF processing functions.

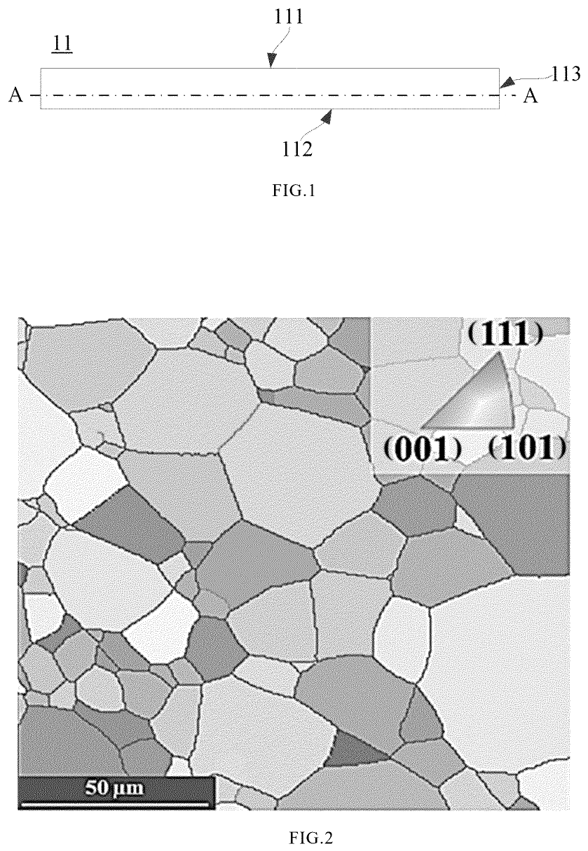

For example, referring to FIG. 2, which shows the IPF coloring diagram of a 150 μm×150 μm region (i.e., the observation region) on the main support surface 111 of a carrier substrate 11 (referred to as Sample 1) provided in one embodiment of the present disclosure, the carrier substrate 11 is a magnesium aluminate spinel substrate having an average grain size of 60 μm. In the region shown in FIG. 2, the proportion of (101)-oriented crystal grains is 14.2%. A filter chip (Chip 1) manufactured using Sample 1 was tested, and its Q value reached 1678.

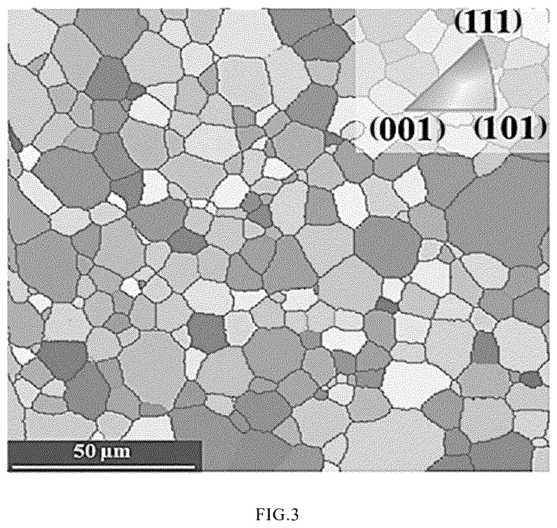

Referring to FIG. 3, which shows the IPF coloring diagram of a 150 μm×150 μm region on the main support surface 111 of a carrier substrate 11 (referred to as Sample 2) provided in another embodiment of the present disclosure, the carrier substrate 11 is a magnesium aluminate spinel substrate having an average grain size of 25 μm. In the region shown in FIG. 3, the proportion of (101)-oriented crystal grains is 12.9%. A filter chip (Chip 2) manufactured using Sample 2 was tested, and its Q value reached 1450.

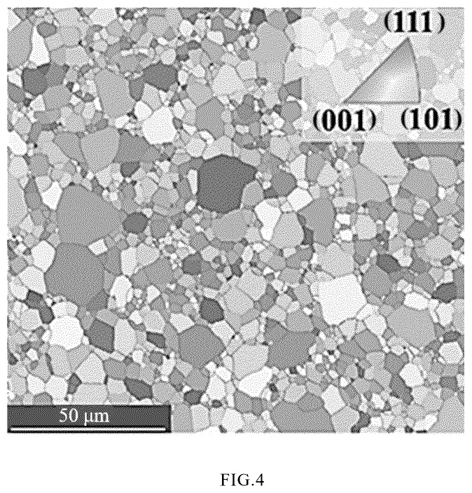

Referring to FIG. 4, which shows the IPF coloring diagram of a 150 μm×150 μm region on the main support surface 111 of a carrier substrate 11 (referred to as Sample 3) provided in yet another embodiment of the present disclosure, the carrier substrate 11 is a magnesium aluminate spinel substrate having an average grain size of 3 μm. In the region shown in FIG. 4, the proportion of (101)-oriented crystal grains is 9.9%. A filter chip (Chip 3) manufactured using Sample 3 was tested, and its Q value reached 1325.

Referring to FIG. 5, which shows the IPF coloring diagram of a 150 μm×150 μm region on the main support surface 111 of a carrier substrate 11 (referred to as Sample 4) provided in still another embodiment of the present disclosure, the carrier substrate 11 is a magnesium aluminate spinel substrate having an average grain size of 25 μm. In the region shown in FIG. 5, the proportion of (101)-oriented crystal grains is 14.5%. A filter chip (Chip 4) manufactured using Sample 4 was tested, and its Q value reached 1695.

From this, it can be seen that the carrier substrate 11 having a specific proportion of crystal grain orientations in the embodiments of the present disclosure has the effect of improving the Q value.

In some embodiments, the proportion of (101)-oriented crystal grains in the observation region specifically ranges 9% to 20%, in which case a higher Q value can be obtained.

Specifically, in some embodiments, the observation region further contains (001)-oriented crystal grains and (111)-oriented crystal grains, and the proportion of (101)-oriented crystal grains in the observation region is greater than 70% of the proportion of (001)-oriented crystal grains. For example, if the proportion of (001)-oriented crystal grains in the observation region is 12%, then the proportion of (101)-oriented crystal grains in the observation region is greater than 8.4%. The proportion of (001)-oriented crystal grains in the observation region is the ratio of the number of (001)-oriented crystal grains in the observation region to the total number of crystal grains in the observation region. In some embodiments, the proportion of (101)-oriented crystal grains in the observation region is greater than 70% of the proportion of (111)-oriented crystal grains. For example, if the proportion of (111)-oriented crystal grains in the observation region is 12.5%, then the proportion of (101)-oriented crystal grains in the observation region is greater than 8.75%. The proportion of (111)-oriented crystal grains in the observation region is the ratio of the number of (111)-oriented crystal grains in the observation region to the total number of crystal grains in the observation region. From FIGS. 2 to 5, the proportions of (001)-oriented crystal grains and (111)-oriented crystal grains in Samples 1 to 4 can also be obtained, as shown in Table 1. Table 1 also shows the proportions of (101)-oriented crystal grains, (001)-oriented crystal grains, and (111)-oriented crystal grains in samples five to eight. The last row of Table 1 shows the Q values of the chips fabricated from the corresponding samples.

TABLE 1

| | Sample | Sample | Sample | Sample | Sample | Sample | Sample | Sample |
|---|---|---|---|---|---|---|---|---|
| | 1 | 2 | 3 | 4 | 5 | 6 | 7 | 8 |
| Average | 60 | 25 | 3 | 25 | 26 | 23 | 27 | 22 |
| Grain Size | | | | | | | | |
| (μm) | | | | | | | | |
| Proportion | 12.50% | 12.60% | 12.60% | 12.40% | 12.00% | 12.70% | 12.30% | 12.90% |
| of (001)- | | | | | | | | |
| Oriented | | | | | | | | |
| Grains | | | | | | | | |
| Proportion | 14.20% | 12.90% | 9.90% | 14.50% | 14.30% | 9.00% | 7.70% | 6.50% |
| of (101)- | | | | | | | | |
| Oriented | | | | | | | | |
| Grains | | | | | | | | |
| Proportion | 11.70% | 12.20% | 11.30% | 12.10% | 9.20% | 11.40% | 12.30% | 11.70% |
| of (111)- | | | | | | | | |
| Oriented | | | | | | | | |
| Grains | | | | | | | | |
| Q Value | 1678 | 1450 | 1325 | 1695 | 1543 | 1184 | 1078 | 976 |

According to Samples 1 to 7, the proportion of (101)-oriented crystal grains is greater than 7% in all cases, and the corresponding Q values can all reach over 1000, thus achieving a relatively high Q value. Comparing Samples 2 and 4, when the proportions of (001)-oriented crystal grains and (111)-oriented crystal grains are kept basically unchanged and the proportion of (101)-oriented crystal grains is increased, the Q value is significantly higher. According to Samples 1, 2, 4, and 5, when the proportion of (101)-oriented crystal grains is greater than the proportions of both (001)-oriented crystal grains and (111)-oriented crystal grains, a higher Q value can be obtained. According to Sample 8, when the proportion of (101)-oriented crystal grains is about 50% of the proportions of (001)-oriented crystal grains and (111)-oriented crystal grains, and the proportion of (101)-oriented crystal grains is less than 7%, the Q value is relatively low. According to Sample 7, when the proportion of (101)-oriented crystal grains is about 60% of the proportions of (001)-oriented crystal grains and (111)-oriented crystal grains, and the proportion of (101)-oriented crystal grains is greater than 7%, the Q value is higher than that of Sample 8. According to Sample 6, when the proportion of (101)-oriented crystal grains is between 70% and 80% of the proportions of (001)-oriented crystal grains and (111)-oriented crystal grains, the Q value is higher than those of Samples 8 and 7. According to Sample 3, when the proportion of (101)-oriented crystal grains is 80% of the proportion of (111)-oriented crystal grains, the Q value can basically meet the requirement (Q value of 1000 or more).

Table 2 shows the Young's Modulus values (which can be measured by preparing magnesium aluminate substrates of the corresponding orientations) and the corresponding Electromechanical Coupling Coefficients (which can be obtained by bonding magnesium aluminate substrates of the corresponding orientations with piezoelectric materials, fabricating chips, and then measuring the chips) for (001)-oriented crystal grains, (101)-oriented crystal grains, and (111)-oriented crystal grains.

TABLE 2

| | | Electromechanical Coupling |
|---|---|---|
| | Young's Modulus (GPa) | Coefficient(K²) |
| (001) | 273 | 7.2 |
| Orientation | | |
| (101) | 265 | 7.4 |
| Orientation | | |
| (111) | 275 | 7.1 |
| Orientation | | |

Based on the comparison of the data in Table 2, the (101)-oriented crystal grains have the smallest Young's modulus and the largest corresponding K², resulting in a wider bandwidth and, therefore, enabling a higher Q value.

In some specific embodiments, the number of (001)-oriented crystal grains in the carrier substrate 11 accounts for 10% to 20% of the total number of crystal grains in the carrier substrate, for example, 10%, 11%, 15%, and the like. More specifically, the proportion of (001)-oriented crystal grains ranges from 10% to 15%, and still more specifically, the proportion ranges from 11% to 14%.

In some specific embodiments, the number of (111)-oriented crystal grains in the carrier substrate 11 accounts for 8% to 17% of the total number of crystal grains in the carrier substrate, for example, 10%, 12%, 13%, 17%, and the like. More specifically, the proportion of (111)-oriented crystal grains is 9% to 17%, and still more specifically, the proportion is 9% to 13%.

In some embodiments, the number of (101)-oriented crystal grains on the main support surface 111 accounts for more than or equal to 7% of the total number of crystal grains on the main support surface 111, and more specifically, 10% to 20%. The number of (001)-oriented crystal grains on the main support surface 111 accounts for 10% to 20% of the total number of crystal grains on the main support surface 111, and more specifically, 11% to 14%. The number of (111)-oriented crystal grains on the main support surface 111 accounts for 8% to 17% of the total number of crystal grains on the main support surface 111, and more specifically, 9% to 13%.

In some embodiments, on any transverse interface of the carrier substrate 11 that is parallel to the main support surface 111, the number of (101)-oriented crystal grains accounts for more than or equal to 7% of the total number of crystal grains on the transverse interface, and more specifically, 10% to 20%. On any transverse interface of the carrier substrate 11 that is parallel to the main support surface 111, the number of (001)-oriented crystal grains accounts for 10% to 20% of the total number of crystal grains on the transverse interface, and more specifically, 11% to 14%. On any transverse interface of the carrier substrate 11 that is parallel to the main support surface 111, the number of (111)-oriented crystal grains accounts for 8% to 17% of the total number of crystal grains on the transverse interface, and more specifically, 9% to 13%.

In some embodiments, the carrier substrate 11 further includes a side surface 113 connected between the main support surface 111 and the back surface 112. An observation region of 150 μm×150 μm is selected on the side surface 113, wherein the proportion of (101)-oriented crystal grains in the observation region is also more than or equal to 7%, the proportion of (001)-oriented crystal grains is also 10% to 20%, and the proportion of (111)-oriented crystal grains is also 8% to 17%.

The carrier substrate 11 provided in the embodiments of the present disclosure can be manufactured through steps such as preparing raw material powder, particle size screening, green body pressing, cutting, grinding, and polishing. In the step of preparing the raw material powder, a corresponding sintering aid may be added. For example, if the sintering aid reacts more significantly with (101)-oriented crystal grains and reacts slightly less with (001)-oriented and (111)-oriented crystal grains, then the proportion of (101)-oriented crystal grains can be controlled by adjusting the proportion of the sintering aid, and the proportions of different oriented crystal grains can be controlled to meet target requirements by adjusting the type and proportion of the sintering aid.

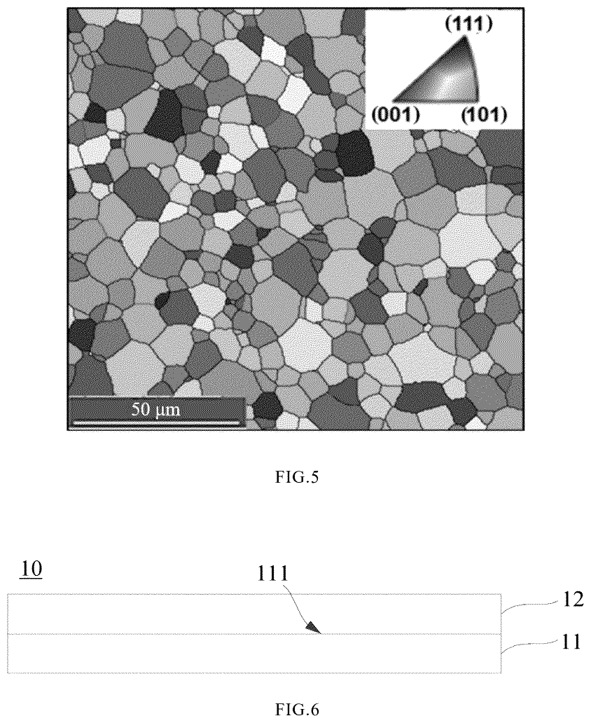

Referring to FIG. 6, an embodiment of the present disclosure further provides a composite substrate 10, which includes a piezoelectric layer 12 and the carrier substrate 11 described in the foregoing embodiments. The piezoelectric layer 12 is disposed on the carrier substrate 11. In some embodiments, the piezoelectric layer 12 and the carrier substrate 11 are bonded to each other, specifically, the piezoelectric layer 12 is bonded to the main support surface 111 of the carrier substrate 11. The two may be directly bonded via van der Waals forces. The piezoelectric layer 12 may be made of, for example, lithium tantalate or lithium niobate. Since the composite substrate 10 uses the aforementioned carrier substrate 11, it exhibits the effect of improving the Q value.

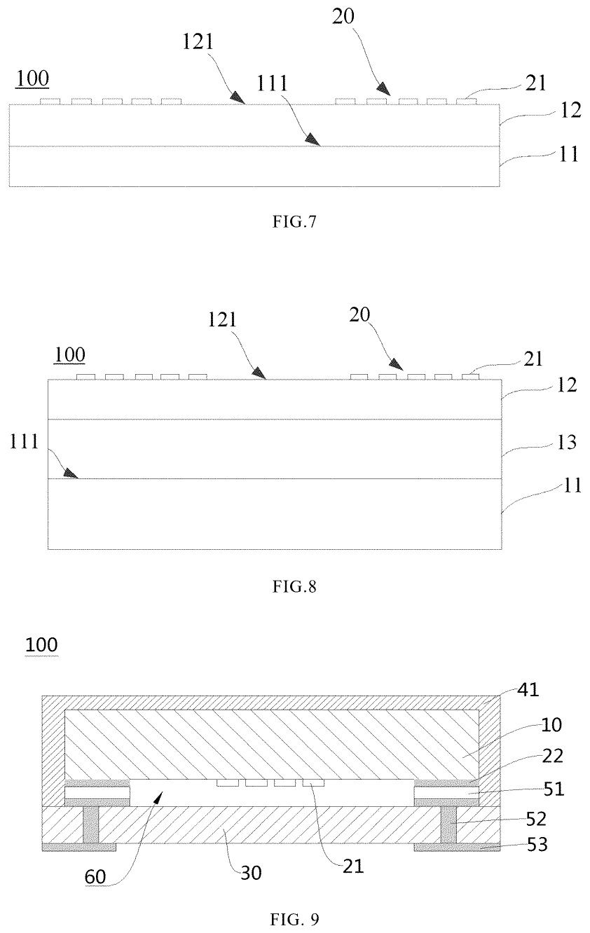

Referring to FIG. 7, an embodiment of the present disclosure further provides an electronic device 100, which includes either the carrier substrate 11 of the foregoing embodiments or the composite substrate 10 of the foregoing embodiments. In the composite substrate 10, the piezoelectric layer 12 may include a main surface 121 facing away from the carrier substrate 11. The electronic device 100 may further include an electrode 20 disposed on the main surface 121, and the electrode 20 may include an IDT electrode 21. The electronic device 100 may be, for example, a SAW device. Since the electronic device 100 includes the carrier substrate 11 of the foregoing embodiments, it exhibits the effect of improving the Q value.

Referring to FIG. 8, in another embodiment of the present disclosure, the electronic device 100 (or composite substrate 10) further includes an intermediate layer 13, which is disposed between the piezoelectric layer 12 and the carrier substrate 11. The acoustic velocity of the intermediate layer 13 is lower than that of the piezoelectric layer 12. That is, compared with the bulk waves propagating in the piezoelectric layer 12, the acoustic velocity of the bulk waves in the intermediate layer 13 is lower. In this embodiment, by providing a low acoustic velocity intermediate layer 13, the acoustic velocity of the elastic waves can be reduced, causing the elastic wave energy to be concentrated in the low-velocity medium (i.e., the intermediate layer 13), thereby reducing loss and improving the Q value.

The material of the intermediate layer 13 may be any one of silicon oxide, silicon oxynitride, tantalum oxide, or a material containing any of these as a main component. In some embodiments, the intermediate layer 13 is made of silicon oxide, and the piezoelectric layer 12 is made of lithium tantalate. The elastic constant of lithium tantalate has a negative temperature characteristic, while silicon dioxide has a positive temperature characteristic, which can reduce the absolute value of the TCF (temperature coefficient of frequency) of the elastic wave device. Furthermore, the intrinsic acoustic impedance of silicon oxide is lower than that of lithium tantalate, thereby increasing the electromechanical coupling coefficient of the electronic component.

In some embodiments, the thickness of the intermediate layer 13 is more than or equal to 0.5λ, where λ is the wavelength of the elastic wave determined by the electrode pitch of the IDT electrode 21. Specifically, the thickness of the intermediate layer 13 may be 0.6-0.8λ. In some embodiments, the thickness of the piezoelectric layer 12 is less than or equal to 22, and specifically, the thickness of the piezoelectric layer 12 may be less than 1λ. In one specific embodiment, λ is 2.25 micrometers, the thickness of the piezoelectric layer 12 is 0.1λ-1λ, and the thickness of the intermediate layer 13 is 0.6λ.

The electronic device 100 provided in this embodiment may employ a Chip Scale Package (CSP) or a Wafer Level Package (WLP).

For example, referring to FIG. 9, which is a schematic structural diagram of an electronic device 100 using CSP packaging, the electronic device 100 includes a component (including the composite substrate 10 and the electrode 20), a package substrate 30, a first sealing structure 41, and a first external terminal electrode 53. The package substrate 30 is disposed opposite to the surface of the component where the electrode 20 is located (i.e., the main surface 121 of the piezoelectric layer 12), and a gap 60 is formed between the package substrate 30 and the main surface 121. The first sealing structure 41 is provided on the side of the package substrate 30 facing the component, covering the side surfaces of the component and the surface opposite to the package substrate 30, so as to seal the gap 60 and hermetically seal the component. The electrode 20 includes an electrode pad 22 electrically connected to the IDT electrode 21. The electrode pad 22 is electrically connected to a first conductive portion 52 in the wiring pattern on the package substrate 30 via a bump 51. The first conductive portion 52 is electrically connected to the first external terminal electrode 53 located on the side of the package substrate 30 opposite to the component, thereby enabling electrical connection between the electronic device 100 and an external device via the first external terminal electrode 53.

The materials of the package substrate 30 and the first sealing structure 41 may be those commonly used in conventional CSP packaging for substrate materials and sealing materials. The electrode pad 22, bump 51, first conductive portion 52, and first external terminal electrode 53 are all made of materials with good electrical conductivity, and the present embodiment is not limited to the above examples.

Referring to FIG. 10, which is a schematic structural diagram of an electronic device 100 using WLP packaging, the electronic device 100 includes a component (including the composite substrate 10 and the electrode 20), a cover 70, a second sealing structure 42, and a second external terminal electrode 55. The cover 70 is disposed opposite to the surface of the component having the electrode 20 (i.e., the main surface 121 of the piezoelectric layer 12), and a gap 60 is formed between the cover 70 and the main surface 121. The electrode 20 includes an electrode pad 22 electrically connected to the IDT electrode 21. The region on the main surface 121 where the IDT electrode 21 is provided is referred to as the active region. The second sealing structure 42 is disposed between the cover 70 and the component and surrounds the active region. The second sealing structure 42 encloses the electrode pad 22 to achieve sealing of the component. The second external terminal electrode 55 provided on the surface of the cover 70 opposite to the component is connected to the electrode pad 22 via a second conductive portion 54 penetrating through the cover 70 and the second sealing structure 42, thereby enabling the electronic device 100 to be electrically connected to an external device via the second external terminal electrode 55.

The materials of the cover 70 and the second sealing structure 42 may be those used for cover materials and sealing materials in conventional WLP packaging. The electrode pad 22, second conductive portion 54, and second external terminal electrode 55 are all made of materials with good electrical conductivity, and the present embodiment is not limited thereto.

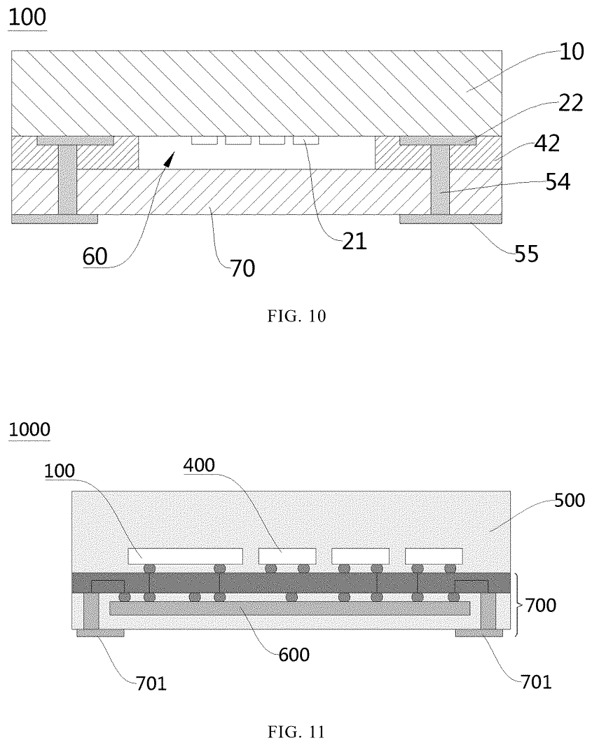

Referring to FIG. 11, the disclosure further provides a module 1000, which includes a wiring substrate 700, a plurality of external connection terminals 701, an integrated circuit component 600, an electronic device 100 (including the composite substrate 10), an inductor 400, and a sealing portion 500. The plurality of external connection terminals 701 are formed on one surface of the wiring substrate 700 and are mounted on the motherboard of a predetermined mobile communication terminal. The integrated circuit component 600 (which may be referred to as an IC) is mounted inside the wiring substrate 700. The integrated circuit component 600 includes a switching circuit and a low-noise amplifier. The electronic device 100 is mounted on the main surface of the wiring substrate 700. The inductor 400 is used for impedance matching and, for example, may be an Integrated Passive Device (IPD). The sealing portion 500 is used to hermetically seal a plurality of electronic components, including the electronic device 100, on the wiring substrate 700.

The module 1000 provided in this embodiment includes the electronic device 100, and thus also includes the carrier substrate 11, thereby exhibiting the same effects as the carrier substrate 11, which will not be repeated here.

The foregoing description merely represents preferred embodiments of the present disclosure and is not intended to limit the disclosure in any way. Although the disclosure has been disclosed through the above embodiments, those skilled in the art may make minor modifications or equivalent changes without departing from the scope of the disclosure. All such modifications, equivalent alterations, and improvements shall fall within the scope of the present disclosure as defined by its technical essence. Of course, the present disclosure is not limited to the embodiments described above, but rather encompasses all embodiments capable of achieving the objectives of the disclosure. It should be understood that the present disclosure includes all implementations that achieve the objectives described herein, and is not restricted solely to the specific embodiments disclosed.

Although various aspects of some embodiments have been described, it will be readily apparent to those skilled in the art that various modifications, improvements, and enhancements may be made. Such modifications, improvements, and enhancements are intended to be part of the disclosure and fall within the scope of this disclosure.

It should be understood that the embodiments of the methods and devices described herein are not limited to the configurations and arrangements illustrated or described above. The methods and devices may be realized in other forms and may be implemented or carried out in various ways.

The specific examples provided are for illustrative purposes only and are not intended to be limiting in any way.

The expressions and terms used in this disclosure are for the purpose of illustration and should not be construed as limiting. Terms such as “comprise,” “include,” “have,” “contain,” and variations thereof are intended to include the items listed thereafter as well as equivalents and additional items.

References to “or” are intended to be inclusive, meaning that any of the listed terms may apply individually, in combination, or collectively.

Directional expressions such as front, back, top, bottom, left, right, vertical, horizontal, inside, and outside are used merely for the sake of descriptive convenience. Such expressions do not restrict the components of the disclosure to any particular spatial position or orientation. Accordingly, the above descriptions and drawings are merely illustrative in nature.

What is claimed is:

1. A substrate, comprising a carrier substrate formed from a polycrystalline material having a main support surface, wherein an observation region on the main support surface or on any transverse interface parallel to the main support surface contains (101)-oriented crystal grains, and a proportion of the (101)-oriented crystal grains in the observation region is 7% to 20% of a total number of grains in the observation region, and wherein the observation region measures 150 μm×150 μm.

2. The substrate according to claim 1, wherein the grains in the carrier substrate have a spinel-type structure.

3. The substrate according to claim 1, wherein the observation region further contains (001)-oriented crystal grains, and the proportion of (101)-oriented crystal grains in the observation region is ≥70% of a proportion of (001)-oriented crystal grains.

4. The substrate according to claim 1, wherein a quantity of (101)-oriented grains in the observation region exceeds that of (001)-oriented crystal grains.

5. The substrate according to claim 1, wherein a proportion of the (001)-oriented crystal grains in the observation region is 10% to 20% of a total number of grains in the observation region.

6. The substrate according to claim 1, wherein the observation region further contains (111)-oriented crystal grains, and the proportion of (101)-oriented crystal grains in the observation region exceeds 70% of the proportion of (111)-oriented grains.

7. The substrate according to claim 1, wherein the observation region further contains (111)-oriented crystal grains, and the quantity of (101)-oriented crystal grains in the observation region exceeds that of (111)-oriented crystal grains.

8. The substrate according to claim 1, wherein the observation region further contains (111)-oriented crystal grains, and a proportion of the (111)-oriented crystal grains in the observation region is 10% to 17% of a total number of grains in the observation region.

9. The substrate according to claim 1, wherein the proportion of the (101)-oriented crystal grains in the observation region is 9% to 20% of a total number of grains in the observation region.

10. The substrate according to claim 1, wherein the observation region further contains (111)-oriented crystal grains and (001)-oriented crystal grains, wherein a proportion of the (111)-oriented crystal grains is 8% to 17% of a total number of grains in the observation region, and a proportion of the (001)-oriented crystal grains is 10% to 15% of a total number of grains in the observation region.

11. The substrate according to claim 1, wherein further comprising a piezoelectric layer provided on the main support surface of the carrier substrate.

12. The substrate according to claim 11, further comprising an intermediate layer provided between the carrier substrate and the piezoelectric layer, wherein the intermediate layer has an acoustic velocity lower than that of the piezoelectric layer.

13. The substrate according to claim 11, further comprising an intermediate layer provided between the carrier substrate and the piezoelectric layer, wherein the intermediate layer has a positive temperature coefficient.

14. An electronic device comprising:
a substrate, comprising a carrier substrate formed from a polycrystalline material having a main support surface, wherein an observation region on the main support surface or on any transverse interface parallel to the main support surface contains (101)-oriented crystal grains, and a proportion of the (101)-oriented crystal grains in the observation region is 7% to 20% of a total number of grains in the observation region, and wherein the observation region measures 150 μm×150 μm;
a piezoelectric layer provided on the main support surface of the carrier substrate; and
an IDT electrode provided on a main surface of the piezoelectric layer opposite to the carrier substrate.

15. The electronic device according to claim 14, further comprising an intermediate layer provided between the carrier substrate and the piezoelectric layer, wherein the intermediate layer has an acoustic velocity lower than that of the piezoelectric layer.

16. The electronic device according to claim 15, wherein the intermediate layer has a thickness of more than or equal to 0.5λ, where λ is a wavelength of an elastic wave defined by a pitch of the IDT electrode.

17. The electronic device according to claim 15, wherein the intermediate layer has a positive temperature coefficient.

18. The electronic device according to claim 15, wherein the intermediate layer comprises a material selected from silicon oxide, silicon oxynitride, tantalum oxide, or materials predominantly composed thereof.

19. The electronic device according to claim 14, wherein the piezoelectric layer has a thickness of less than or equal to 2λ, where λ is a wavelength of an elastic wave defined by a pitch of the IDT electrode.

20. A module comprising a wiring substrate, a plurality of external connection terminals, an integrated circuit component, an inductor, a sealing portion, and the electronic device according to claim 14.
